(19) United States
(12) Patent Application Publication
(10) Pub. No.: US 2026/0331152 A1
(43) Pub. Date: Oct. 22, 2026

(54) DDR Magnetic Memory System Incorporating Pseudo Synchronous Interface

(71) Applicant: Avalanche Technology, Inc., Fremont, CA (US)

(72) Inventors: Dean K. Nobunaga, Cupertino, CA (US); Uday Chandrasekhar, Milpitas, CA (US); Mourad El Baraji, Livermore, CA (US); Thinh Tran, Palo Alto, CA (US); Jun Li, Fremont, CA (US); Frederick T. Jaffin, San Jose, CA (US); Ebrahim Abedifard, San Jose, CA (US)

(21) Appl. No.: 19/315,782

(22) Filed: Sep. 1, 2025

Related U.S. Application Data
(60) Provisional application No. 63/791,654, filed on Apr. 20, 2025.

(51) Int. Cl. G11C 11/16

(52) U.S. Cl. CPC G11C 11/1675; G11C 11/1655; G11C 11/1673; G11C 11/1693

(57) ABSTRACT

A magnetic memory system includes a plurality of magnetic random access memory (MRAM) dies, each MRAM die including a plurality of magnetic memory cells; and a circuitry residing on an application-specific integrated circuit (ASIC) die for controlling the MRAM dies, the circuitry communicating with devices external to the magnetic memory system through an external interface and the MRAM dies through an internal interface, wherein the external interface is in compliance with a version of Double Data Rate (DDR) standards and has a data transfer rate corresponding to a sum of data transfer rates of the MRAM dies. The ASIC die and the MRAM dies may be packaged together or separately attached to a printed circuit board.

### CROSS-REFERENCE TO RELATED APPLICATIONS

The present application claims priority to provisional Application No. 63/791,654, filed on Apr. 20, 2025, the content of which is incorporated herein by reference in its entirety.

### BACKGROUND OF THE INVENTION

The present invention relates to magnetic memory, and more particularly, to a magnetic random access memory (MRAM) system having a double data rate (DDR) interface to mimic or emulate dynamic random access memory (DRAM).

A resistance-switching non-volatile memory device, such as spin-transfer torque (STT) MRAM, normally comprises a plurality of non-volatile memory cells, each of which includes a memory element and a selection element, such as access transistor, coupled in series between two electrodes. The selection element functions as a switch to direct current or voltage through the selected memory element coupled thereto. Upon application of an appropriate voltage or current to the selected memory element, the resistance of the memory element changes accordingly, thereby switching the stored logic in the respective memory cell.

FIG. 1 is a schematic circuit diagram showing a resistance-switching memory array 20, which comprises a plurality of memory cells 22 arranged in rows and columns with each of the memory cells 22 including an access transistor 24 coupled to a resistance-switching memory element 26; a plurality of parallel word lines 28 with each being coupled to the gates of a respective row of the access transistors 24 in a first direction; a plurality of parallel bit lines 30 with each being coupled to a respective column of the memory elements 26 in a second direction substantially perpendicular to the first direction; and a plurality of parallel source lines 32 with each being coupled to a respective column of the access transistors 24 in the second direction.

Unlike traditional memories (SRAM, DRAM, Flash) that store data as electrical charges in capacitor-like structures or floating gates, MRAM stores data in a memory element comprising at least a magnetic tunnel junction (MTJ). FIGS. 2A, 2B show a magnetic memory cell 22 comprising a magnetic memory element 26 and an access transistor 24 coupled in series. The magnetic memory element 22 include a magnetic reference layer 54, a magnetic free layer 56, and an electron tunnel junction layer 58 interposed therebetween. The magnetic reference layer 54, the magnetic free layer 56, and the electron tunnel junction layer 58 collectively form a MTJ. Upon the application of an appropriate current or voltage to the MTJ, the magnetization direction 60 of the magnetic free layer 56 can be switched between two directions: parallel (FIG. 2A) and anti-parallel (FIG. 2B) with respect to the magnetization direction 62 of the magnetic reference layer 54 (i.e., STT-MRAM). When the magnetization directions 60, 62 of the magnetic free and reference layers 56, 54 are substantially parallel or oriented in a same direction (FIG. 2A), electrons polarized by the magnetic reference layer 54 can tunnel through the insulating tunnel junction layer 58, thereby decreasing the electrical resistance of the MTJ. Conversely, the electrical resistance of the MTJ is high when the magnetization directions 60, 62 of the magnetic free and reference layers 56, 54 are substantially anti-parallel or oriented in opposite directions (FIG. 2B). Accordingly, the stored logic in the memory element 26 can be switched by changing the magnetization direction 60 of the magnetic free layer 56 between parallel and anti-parallel with respect to the magnetization direction 62 of the magnetic reference layer 54.

In addition to being non-volatile and having reduced power consumption in standby modes, MRAM exhibits inherent resistance to radiation, making it well-suited for applications in harsh environments like space and avionics. Most working memory for current computational devices utilizes DRAM, which has DDR interfaces. Enabling compatibility with DDR memory interfaces will make MRAM particularly suitable for space applications such as boot memory, persistent storage, and high-reliability computing.

For the foregoing reasons, there is a need for a cost-effective MRAM system that appears to CPUs and memory controllers of computational systems as if the MRAM system were conventional DRAM, requiring minimal or no changes to the existing computational system architecture.

### SUMMARY OF THE INVENTION

The present invention is directed to a MRAM system that satisfies this need. A magnetic memory system includes a plurality of magnetic random access memory (MRAM) dies, each MRAM die including a plurality of magnetic memory cells; and a circuitry residing on an application-specific integrated circuit (ASIC) die for controlling the MRAM dies, the circuitry communicating with devices external to the magnetic memory system through an external interface and the MRAM dies through an internal interface, wherein the external interface is in compliance with a version of Double Data Rate (DDR) standards and has a data transfer rate corresponding to a sum of data transfer rates of the MRAM dies. The ASIC die and the MRAM dies are packaged together or separately attached to a printed circuit board. Each MRAM die includes multiple memory banks, each memory bank including multiple arrays of magnetic memory cells, each array of magnetic memory cells including multiple sub-arrays of magnetic memory cells, each sub-array of magnetic memory cells being arranged in rows and columns with a plurality of parallel bit lines connecting each sub-array of magnetic memory cells along a column direction.

According to another aspect of the present invention,

### BRIEF DESCRIPTION OF DRAWINGS

These and other features, aspects, and advantages of the present invention will become better understood with regard to the following description, appended claims, and accompanying drawings where:

FIG. 1 is a schematic circuit diagram for an array of memory cells with each memory cell including a resistance-based memory element and an access transistor coupled in series;

FIGS. 2A and 2B illustrate a magnetic memory cell, including a MTJ, in low and high resistance states, respectively;

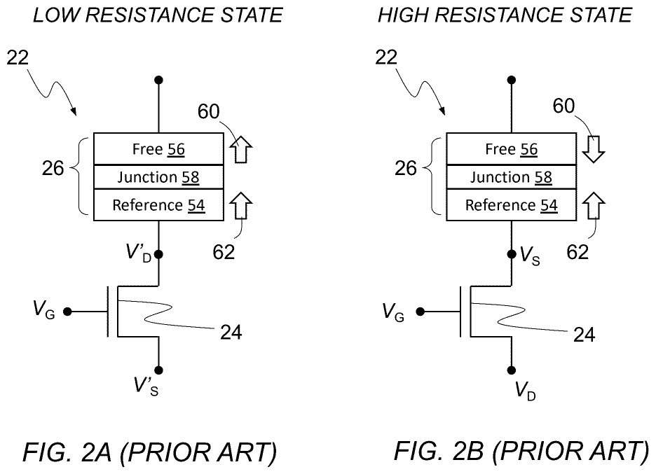

FIG. 3 is a block diagram illustrating a MRAM system having a DDRx external interface in accordance with an embodiment of the present invention;

FIG. 4 is a cross-sectional view showing an example of the MRAM system in a packaged form;

FIG. 5 is a block diagram illustrating the internal interface of the MRAM system between one of the MRAM dies and the circuitry for controlling the MRAM dies;

FIG. 6 is a timing diagram illustrating the relationship between the external DDR4 signals of the external interface and corresponding internal signals of the internal interface when the MRAM system receives two external ACTIVATE commands;

FIG. 7 is a timing diagram illustrating the relationship between the external DDR4 signals of the external interface and corresponding internal signals of the internal interface when the MRAM system receives two external PRECHARGE commands;

FIG. 8 is a timing diagram illustrating the relationship between the external DDR4 signals of the external interface and corresponding internal signals of the internal interface when the MRAM system receives two external READ commands; and

FIG. 9 is a timing diagram illustrating the relationship between the external DDR4 signals of the external interface and corresponding internal signals of the internal interface when the MRAM system receives two external WRITE commands.

For purposes of clarity and brevity, like elements and components will bear the same designations and numbering throughout the Figures, which are not necessarily drawn to scale.

### DETAILED DESCRIPTION OF THE INVENTION

In the Summary above and in the Detailed Description, and the claims below, and in the accompanying drawings, reference is made to particular features (including method steps) of the invention. It is to be understood that the disclosure of the invention in this specification includes all possible combinations of such particular features. For example, where a particular feature is disclosed in the context of a particular aspect or embodiment of the invention, or a particular claim, that feature can also be used, to the extent possible, in combination with and/or in the context of other particular aspects and embodiments of the invention, and in the invention generally.

Where reference is made herein to a method comprising two or more defined steps, the defined steps can be carried out in any order or simultaneously, except where the context excludes that possibility, and the method can include one or more other steps which are carried out before any of the defined steps, between two of the defined steps, or after all the defined steps, except where the context excludes that possibility.

The term “at least” followed by a number is used herein to denote the start of a range beginning with that number, which may be a range having an upper limit or no upper limit, depending on the variable being defined. For example, “at least 1” means 1 or more than 1. The term “at most” followed by a number is used herein to denote the end of a range ending with that number, which may be a range having 1 or 0 as its lower limit, or a range having no lower limit, depending upon the variable being defined. For example, “at most 4” means 4 or less than 4, and “at most 40%” means 40% or less than 40%. When, in this specification, a range is given as “a first number to a second number” or “a first number-a second number,” this means a range whose lower limit is the first number and whose upper limit is the second number. For example, “25 to 100 nm” means a range whose lower limit is 25 nm and whose upper limit is 100 nm.

Directional terms, such as “front,” “back,” “top,” “bottom,” and the like, may be used with reference to the orientation of the illustrated figure. Spatially relative terms, such as “beneath,” “below,” “under,” “lower,” “upper,” “above,” etc., may be used herein to describe one element's relationship to another element(s) as illustrated in the figure. Since articles and elements can be positioned in a number of different orientations, these terms are intended for illustration purposes and in no way limit the invention, except where the context excludes that possibility.

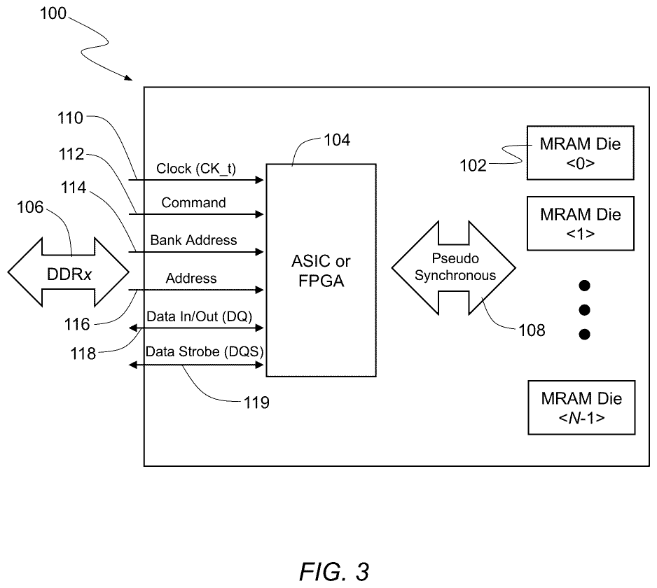

FIG. 3 is a block diagram illustrating a MRAM system having an external DDRx (e.g., DDR4) interface in accordance with an embodiment of the present invention. The MRAM system 100 comprises magnetic random access memory (MRAM) 102 in the form of one or more MRAM chips or dies (Die <0> to Die <N−1>) and a circuitry 104 in the form of an application-specific integrated circuit (ASIC) or field programmable gate arrays (FPGA) die or chip. The circuitry 104 of the MRAM system 100 communicates with the CPU, and/or memory controller, and/or other components of a computational system through an external interface 106 that conforms to or is compatible with a DDRx (e.g., DDR4) interface. The MRAM dies 102 communicate with the circuitry 104 through an internal system interface 108 that utilizes an event-based timing scheme. Therefore, the circuitry 104 converts commands and transfer data between the external interface 106 and the internal interface 108, thereby serving as a bridge that enables the MRAM dies 102 that use the internal system interface 108 to communicate with other components (e.g., CPU, memory controller) of the computational system that are compatible with the DDRx interface.

The external interface 106, which conforms to or is compatible to a DDRx interface, may have a clock speed of Y MHz and a data bus width of Z bits, resulting in a double data transfer rate of YZ/4 MB/s. Corresponding to the DDRx-compatible external interface 106, N number of MRAM dies 102 (Die <0> to Die <N−1>), each of which has a clock speed of y MHz, a total data bus width of z bits, and a resulting data transfer rate of yz/8 MB/s (for single data rate or SDR), are needed to at least match the data transfer rate of the external interface 106. In an embodiment, the data transfer rate of each MRAM die 102 is a fraction of that of the external interface 106 and the number of the MRAM dies 102 needed would correspond to the data transfer rate of the external interface 106 divided by the data transfer rate of the MRAM die 102. For example, to emulate or mimic an 8 Gb DDR4-SDRAM chip with an 800 MHz clock speed, a 16 bits data bus, and a data transfer rate of 3200 MB/s, the MRAM system 100 would need four (N=4) 2 Gb MRAM dies 102 with a 200 MHz clock speed and a 32-bit data bus (SDR). Furthermore, to emulate or mimic a 16 Gb DDR 4-SDRAM chip with a 1600 MHz clock speed, a 16 bits data bus, and a data transfer rate of 6400 MB/s, the MRAM system 100 may use eight (N=8) of the same MRAM dies 102. The examples illustrate an important advantage of the present invention: the ease of scaling the MRAM system 100 to match different DDRx interfaces with the same MRAM dies 102, which would significantly reduce the product development costs and time compared to developing a MRAM die with a native DDRx compatible interface.

With continued reference to FIG. 3, the DDRx-compatible external interface 106 provides a plurality of inputs to the MRAM system 100 including an external Clock input (CK_t/CK_c) 110, an external Command input 112, an external Bank Address input (BA) 114, and an external Address input (Add) 116. Additionally, an external Data input/output (DQ) 118, together with an external Data strobe (DQS) 119, for providing write data to and receiving read data from the MRAM system 100.

The external Clock input (CK_t/CK_c) 110, which may be different from the system clock, provides a differential clock signal that synchronize operations between the memory controller/CPU and the memory. The CK_t (Clock True) and CK_c (Clock Complement) signals are the positive and inverted signals of the differential pair, respectively. All address, command, and control input signals are sampled at the crossing of the positive edge of CK_t and the negative edge of CK_c, which means the effective clock event for sampling occurs when CK_t is rising and CK_c is simultaneously falling. Additionally, the external interface 106, which is conformed to the double data rate (DDR) protocol, allows the transfer of data on both the rising and falling edges of the clock signal, which effectively doubles the data transfer rate without increasing the actual clock frequency.

The external Command input 112 includes Activate (ACT_n), Chip Select (CS_n), Row Address Strobe (RAS_n), Column Address Strobe (CAS_n), and Write Enable (WE_n) signals, which in combination provide various standard commands to DRAM, such as ACTIVATE, PRECHARGE, READ, and WRITE. The ACTIVATE command, in the context of DRAM technology, opens or activates a row of memory cells within a memory bank, which comprises a plurality of memory cells arranged in rows and columns, and transfer the data stored in the row of memory cells to corresponding sense amplifiers, which also serve as data latches. The PRECHARGE command, in the context of DRAM technology, closes an open (active) row of memory cells within a specific memory bank, or across all banks, and restore the voltages of bit lines connected to the row of memory cells to a specified voltage, typically half the supply voltage. The READ command, in the context of DRAM technology, retrieves a contiguous block or burst of data stored in the sense amplifiers/data latches from a previously activated row of memory cells within a specific DRAM memory bank and transfer the data to the Data input/output (DQ) 118. For example, the standard burst length for each DDR4 READ or WRITE command may be 4 clock cycles, which correspond to 8 data cycles. The WRITE command, in the context of DRAM technology, transfers a burst of data from the Data input/output (DQ) 118 and store them into a specific location in a previously activated row of memory cells within a DRAM memory bank.

The external Bank Address input (BA) 114 includes Bank Group Address (BG) and Bank Address (BA) signals. The Bank Group Address (BG) and Bank Address (BA) signals identify the bank group and the bank within the bank group to which an external command, such as ACTIVATE, PRECHARGE, READ, or WRITE, is applied to. The Address input 116 provides a row address for the ACTIVATE command and a column address for the READ/WRITE commands to specify the memory cells within the activated row to which the commands are applied to.

The external Data input/output (DQ) 118, which is conveyed by a bidirectional bus, transfers the read data from the MRAM system 100 to the memory controller or CPU and the write data from the memory controller or CPU to the MRAM system 100. The read or write data is accompanied by a dedicated signal from the Data Strobe (DQS) 119 that is generated by the sender of the data and used by the receiver to accurately capture that data. The signal from DQS 119 is transmitted along with the read or write data through DQ 118 and experiences similar propagation delays and environmental effects, thereby ensuring that the DQS signal is tightly aligned with the data it is strobing. Accordingly, the Data strobe (DQS) 119 provides a “source-synchronous” clock to reduce clock skew and jitter when transferring the read and write data between the MRAM system 100 and the memory controller/CPU.

The DDRx-compatible external interface 106 is a synchronous interface, meaning all changes on control inputs are recognized in relation to the rising edge of the differential clock signal transmitted through the Clock input 110. All address, command, and control signals are sampled at the rising edge of the differential clock signal, while the data is sampled at both the rising and falling edges of the different clock signal (i.e., DDR).

The circuitry 104 in the form of an ASIC/FPGA die and the MRAM dies 102 may be encapsulated and/or packaged together in such a way that the MARM system 100 has the same pin configuration as a packaged DDRx-SDRAM (e.g., DDR4-SDRAM) chip. The ASIC/FPGA die 104 and the MRAM dies 102 in the package may be electrically connected by through-silicon vias (TSVs), wires connected to the package substrate, or a combination thereof.

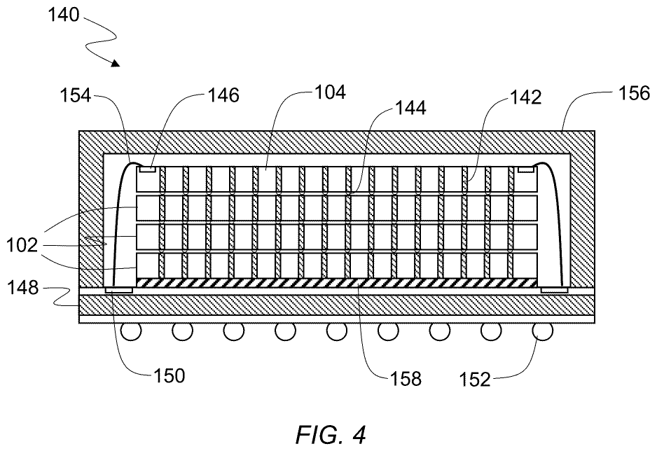

FIG. 4 is a cross-sectional view showing an example of the MRAM system 100 in a packaged form 140, which may be used as a drop-in replacement for a packaged DDRx-SDRAM chip. The packaged MRAM system 140 includes an ASIC/FPGA chip or die 104 and a plurality of MRAM dies 102 stacked on top of each other. Each of the dies 102, 104 has first and second planar surfaces and a plurality of through-thickness vias 142 that extend between the first and second planar surfaces. The through-thickness vias 142, also known as through-silicon vias (TSVs) in the parlance of semiconductor art, of each die 102, 104 may be electrically connected to the vias 142 of the adjacent die(s) by a plurality of interconnect structures 144, such as but not limited to solder bumps and copper micro-bumps, or other analogous conductor structures, thereby allowing the stack of dies 102, 104 to be electrically connected and integrated like a single IC device.

With continued reference to FIG. 4, the packaged MRAM system 140 may further comprise a plurality of die bond pads 146 formed on the first surface of the ASIC/FPGA die 104, which may be disposed on top of the stack; a package substrate 148 having first and second planar surfaces that are substantially larger than the first and second planar surfaces of the stack of dies 102, 104 and extending beyond the stack of dies 102, 104 on opposing sides, the first planar surface of the package substrate 148 being disposed adjacent to the second planar surface of a bottom MRAM die 102 of the stack of dies 102, 104 and including a plurality of package bond pads 150 formed on the first planar surface of the package substrate 148 not covered by the stack of dies 102, 104, the second planar surface of the package substrate 148 including a plurality of solder bumps 152 that are electrically connected to the package bond pads 150; a plurality of bonding wires 154 electrically connecting the die bond pads 146 of the ASIC/FPGA die 104 to the package bond pads 150; and a package cap 156 confronting the first planar surface of the ASIC/FPGA die 104 and having an edge that extends toward and attaches to the package substrate 148, thereby encapsulating the stack of dies 102, 104. The second planar surface of the bottom MRAM die 102 may be bonded to the package substrate 106 by an adhesive material 158, such as but not limited to epoxy, to attach the stack of dies 102, 104 to the package substrate 148.

Additional details concerning the packaging of the MRAM dies 102 may be found in the commonly assigned U.S. Pat. No. 12,278,195, which is incorporated herein by reference in its entirety. The MRAM system 100 may alternatively be constructed of a printed circuit board (PCB) with the MRAM dies 102 and the ASIC/FPGA die 104 separately attaching thereto. The PCB may have a dual in-line memory module (DIMM) form factor, or a variation thereof, such as small outline in-line memory module (SODIMM). Accordingly, the MRAM system 100 may be a drop-in replacement for DDRx-SDRAM at the chip or module level.

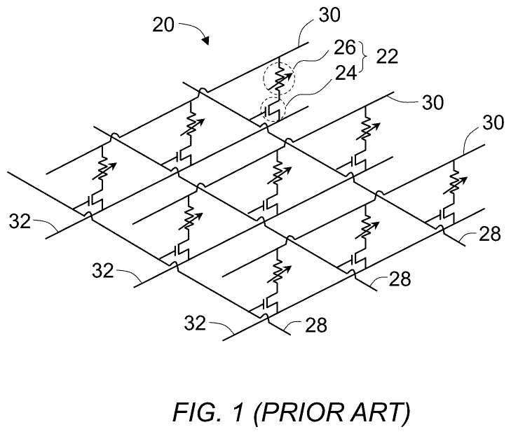

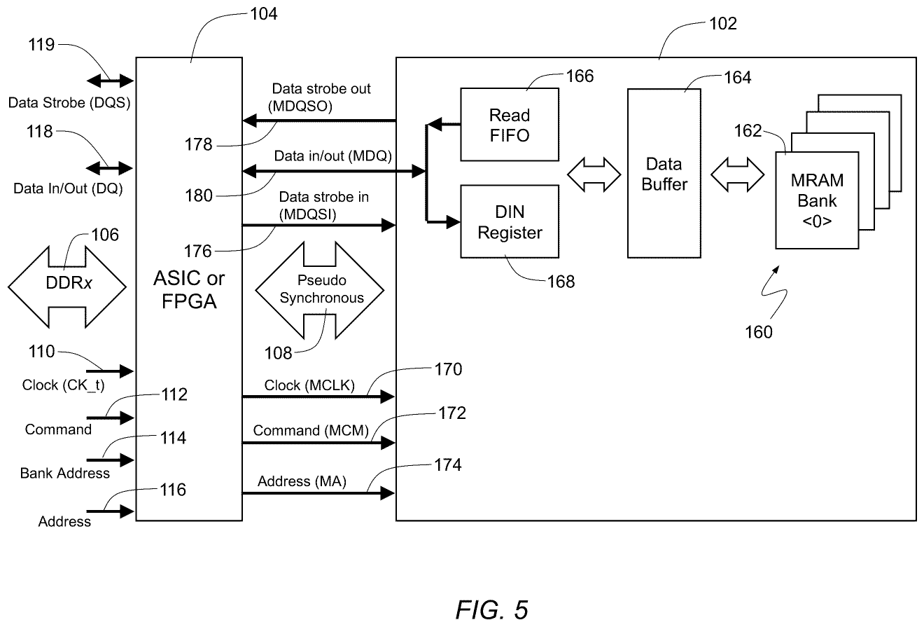

FIG. 5 is a block diagram illustrating one of the MRAM dies 102 (Die <0:N−1>) in the MRAM system 100. Each of MRAM die 102 includes a plurality of memory cells 160 arranged to form P memory banks 162 (Bank <0:P−1>). The memory cells in each memory bank 162 may be further divided to form Q memory arrays (Array <0:Q−1>), each of which may include a plurality of magnetic memory cells arranged in rows and columns as shown in FIG. 1. Each memory array may be further divided into S sub-arrays (Sub-array <0:S−1>) by bit lines. Each sub-array may include U bit lines (BL <0:U−1>) connected to a dedicated sense amplifier through a multiplexer (MUX). Unlike the DRAM architecture where each bit line or a pair of bit lines are connected to a dedicated sense amplifier, multiple bit lines are connected to a dedicated sense amplifier in the MRAM architecture because the more complex sensing scheme for the MRAM cells requires larger sense amplifiers. Examples concerning the sensing scheme of the MRAM cells may be found in the commonly assigned U.S. Pat. Nos. 11,289,142, 11,610,616, and 11,854,591, which are incorporated herein by reference in their entirety. Accordingly, Q·S memory cells (i.e., Q·S bits of data), which may represent a logical row of magnetic memory cells in the context of ACTIVATE and PRECHARGE commands, can be sensed simultaneously in a memory bank 162.

Each MRAM die 102 may further include a data buffer 164 connected to the plurality of memory cells 160 for storing read data from one of the memory banks 162 or write data from the memory controller or CPU, a read FIFO buffer 166 connected to the data buffer 164, a data-in register 168 connected to the data buffer 164, and internal MRAM circuitry (not shown). In an alternative embodiment, the data buffer 164, the read FIFO buffer 166, and the data-in buffer 164 may be relocated in the circuitry 104 residing in the ASIC/FPGA die instead.

The data buffer 164 emulates the row or page buffer of DRAM. However, unlike the page buffer of DRAM which stores data from an entire row of memory cells connected to a word line in a DRAM memory bank, the data buffer 164 stores data that may correspond to multiple word lines of different memory arrays. Moreover, not all magnetic memory cells connected to each activated word line are sensed because multiple bit lines share a sense amplifier through a MUX as described above. Accordingly, the data buffer 164 may store Q·S bits of data corresponding to S sense amplifiers per memory array and Q memory arrays per memory bank. The total page memory size of the MRAM system 100 would therefore be N·Q·S bits when N number of MRAM dies 102 working cooperatively.

The read FIFO buffer 166 is a type of memory queue that temporarily stores data that has been read from the data buffer 164 before transmitting the data off the MRAM die 102 in the same order it was written (i.e., “First-In, First-Out”), thereby preventing data mix-ups and ensuring sequential integrity. The read FIFO buffer 166 fetches and accumulates a block or burst of data (z bits) from the data buffer 164 corresponding to a read command and then clock it out rapidly through an internal bidirectional data bus with a width of at least z bits between the MRAM die 102 and the ASIC/FPGA die 104.

The data-in register 168 latches the incoming write data originated from a write command and transfer the write data to the data buffer 164, thereby ensuring the incoming write data remains stable and available for the internal MRAM circuitry to capture at the exact moment the write data is valid on the internal bidirectional data bus. The data-in register 168 may decouple the write data transfer between the circuitry 104 and the MRAM die 102 from the internal transfer of the write data to the data buffer 164.

With continued reference to FIG. 5, each MRAM die 102 communicates with the circuitry 104 in the form of the ASIC/FPGA die through the internal system interface 108 that includes an internal Clock input (MCLK) 170, an internal Command input 172, an internal Address input (MA) 174, a Data strobe in input (MDQSI) 176, and a Data strobe out output (MDQSO) 178, and a Data input/output (MDQ) 180 for providing data to and from the MRAM die 102.

The internal Clock input (MCLK) 170 is generated by the circuitry 104, which runs off the external Clock signal (CK_t) 110 from the memory controller or CPU. Compared with the external Clock (CK_t) 110 of the DDRx-compatible external interface 106, the internal Clock (MCLK) 170 may have a lower clock frequency to accommodate the lower operating speed of the MRAM die 102. Moreover, the rising or falling edge of MCLK 170 may be triggered from the rising or falling edge of CK_t 110. For example, the clock frequencies of CK_t 110 and MCLK 170 may be 800 MHz and 200 MHz, respectively, with the rising edge of MCLK 170 triggered from the rising or falling edge of CK_t 110. Unlike CK_t 110 which is a time-based, free-running clock, MCLK 170 is an event-based clock that is activated only when the circuitry 104 of the MRAM system 100 receives certain commands, such as ACTIVATE, PRECHARGE, READ, and WRITE, and the commands are executed by the MRAM die 102 internally in a self-timed manner. The use of event-based clock MCLK 170 may reduce the latency of the MRAM die 102, especially when there is a large difference between the clock frequency of the external interface 106 and the operating frequency of the MRAM die 102. Furthermore, the even-based clocking scheme saves power because the internal interface 108 is fully static or inactive when idled or deselected.

The internal Command input (MCM) 172 to the MRAM die 102 is generated by the circuitry 104, in response to the external Command input 114. For example, in response to an external Activate command from the external interface 106 to activate or open a row of DRAM memory cells within a memory bank and latch the corresponding data in the sense amplifiers, the circuitry 104 issues an internal Activate command to each MRAM die 102 through MCM 172 and to activate multiple word lines of different memory arrays as specified by MA 174 to sense the resistance states of the magnetic memory cells connected to the sense amplifiers through MUXs and then transfer the sensed data to the data buffer 164. These sensed magnetic memory cells may not be connected by a single physical word line because the magnetic memory cells in the MRAM banks 162 may be arranged differently compared to the DRAM cells. Accordingly, the sensed magnetic memory cells of each MRAM die 102 in response to the internal ACTIVATE command may represent a logical row of magnetic memory cells.

After receiving an external PRECHARGE command from the external interface 106 to close an open (active) row of DRAM cells within a specific memory bank and restore the voltages of bit lines connected to the row of memory cells to a specified voltage, the circuitry 104 issues an internal PRECHARGE command to each MRAM die 102 through MCM 172 to write the data stored in the data buffer 164 to the magnetic memory cells corresponding to an active logical row.

In response to an external READ command to read a block or burst of data from the DRAM page buffer spanning multiple clock cycles (e.g. 4 clock cycles and 8 data cycles for DDR4), the circuitry 104 issues an internal READ command to each MRAM die 102 through MCM 172 and provides corresponding column addresses through MA 174, which correspond to 1/N fraction of the burst of read data specified by the external READ command, to transfer the read data from the data buffer 164, to the read FIFO buffer 166, to the circuitry 104 through MDQ 180, and to the memory controller or CPU through DQ 118 of the external interface 106. Accordingly, the N number of MRAM chips 102 operating at a lower clock frequency can collectively match the read data transfer rate specified by the external interface 106 for each burst cycle.

After receiving an external WRITE command from the external interface 106 to write a block or burst of data spanning multiple clock cycles (e.g. 4 clock cycles and 8 data cycles for DDR4) from the memory controller or CPU to the DRAM page buffer, the circuitry 104 issues an internal WRITE command through MCM 172 and corresponding column addresses through MA 174 to transfer 1/N fraction of the burst of write data to each of the N number of MRAM dies 102 through MDQ 180. The incoming write data from MDQ 180 is first latched by the data-in register 168 before transferring to the write data buffer 164. Therefore, the N number of MRAM chips 102 operating at a lower clock frequency can collectively match the write data transfer rate specified by the external interface 106 for each burst cycle.

The internal Address input (MA) 174 is generated by the circuitry 104, in response to the external Bank Address 114 and Address 116 accompanying external ACTIVATE, PRECHARGE, READ, or WRITE command. MA 174 may be an address specifying the physical location of the magnetic memory cells mapped or translated from the logical address specified by the external Bank Address 114 and Address 116 provided by the external memory controller or CPU. Alternatively, MA 174 may also be a logical address corresponding to the logical address specified by the external Bank Address 114 and Address 116. In the latter case, the internal address specified by MA 174 may need to be further translated to a physical address by the internal circuitry of the MRAM dies 102 because the magnetic memory cells in the MRAM banks 162 may be arranged differently compared with DRAM cells. MA 174 provides a logical or physical address that specifies the location of the magnetic memory cells within a MRAM bank 162 to which the internal ACTIVATE, PRECHARGE, READ, or WRITE command is directed.

The Data input/output (MDQ) 180, which is conveyed by an internal bidirectional bus, transfers the read data from the MRAM die 102 to the circuitry 104 and the write data from the circuitry 104 to the MRAM die 102. The internal bidirectional bus may have a bus width of at least z bits to accommodate the simultaneous transfer of z bits of data.

The Data strobe input (MDQSI) 176 and the Data strobe output (MDQSO) 178 collectively provide a “source-synchronous” clock to reduce clock skew and jitter when transferring the read data from the read FIFO buffer 166 to the circuitry 104 through MDQ 180. The strobe signal from MDQSI 176 is generated by the circuitry 104 after a specified delayed period or latency following the issuance of an internal READ command. This latency or delayed period, which may be a programmable parameter set during initialization of the MRAM system 100, may allow time for the proper transfer of the read data from the data buffer 164 to the read FIFO buffer 166 before transferring the read data to the circuitry 104 through MDQ 180. While the clock period of MDQSI 176 is same as the internal clock MCLK 170, which may correspond to the operating speed of the MRAM die 102, the strobe signal from MDQSI 176 may be triggered from the external CK_t 110 or phase shifted to reduce latency. Following the strobe signal from MDQSI 176, the read data is transferred from the read FIFO buffer 166 to the circuitry 104 through MDQ 180, together with another strobe signal from MDQSO 178 to ensure the read data is accurately captured by the circuitry 104.

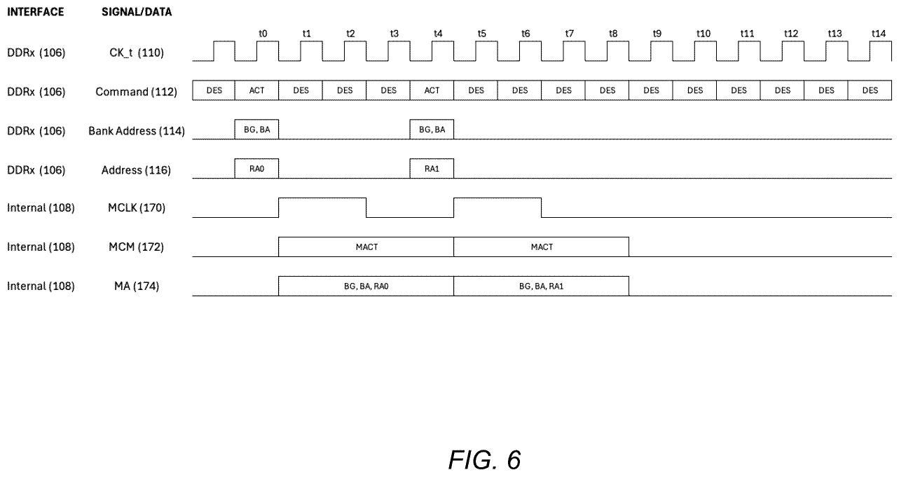

Using the above-described example of four (N=4) 2 Gb MRAM dies 102, each with a 200 MHz clock speed and a 32-bit data bus (SDR), to emulate or mimic an 8 Gb DDR4-SDRAM chip with an 800 MHz clock speed and a 16 bits data bus, FIG. 6 is an exemplary timing diagram showing the relationship between the external DDR4 signals of the external interface 106 and corresponding internal signals of the internal interface 108 when the MRAM system 100 receives two external ACTIVATE commands via the external Command input 112 to activate two rows of two different memory banks in the context of DRAM technology. The circuitry 104 of the MRAM system 100 receives the first ACTIVATE command (ACT), corresponding bank group and bank address (BG, BA) for the first memory bank, and row address (RA0) at CK_t=t0 through the Command input 112, the Bank address input 114, and the Address input 116, respectively. The external Clock (CK_t) 110 may be center-aligned with Command input 112, the Bank address input 114, and the Address input 116, as shown. After receiving the first external ACTIVATE command (ACT) and corresponding addresses, the circuitry 104 issues an internal clock signal, an internal ACTIVATE command (MACT), and corresponding bank group, bank and row addresses (BG, BA, RA0) to the MRAM dies 102 through the internal Clock input (MCLK) 170, the internal Command input 172, and the internal Address input (MA) 174, respectively. The internal clock signal, internal ACTIVATE command (MACT), and corresponding bank group, bank and row addresses (BG, BA, RA0) may be issued as a packet by the circuitry 104. In response to the internal ACTIVATE command (MACT), the logical or resistance states of the magnetic memory cells of the MRAM bank 162, as specified by the internal addresses (BG, BA, RA0), are sensed and transferred to the data buffer 164 for each MRAM die 102. The bank group, bank and row addresses (BG, BA, RA0) transmitted through MA 174 may be logical addresses corresponding to the external logical addresses because the magnetic memory cells in the MRAM banks 162 may be arranged differently compared to the DRAM cells. Accordingly, the internal addresses specified by MA 174 may need to be further translated to physical addresses by the internal circuitry of the MRAM dies 102, and the sensed magnetic memory cells corresponding to the internal ACTIVATE command may represent a logical row of magnetic memory cells formed by the sensed magnetic memory cells from four banks of four different MRAM dies 102.

With continued reference to FIG. 6, the circuitry 104 of the MRAM system 100 receives the second external ACTIVATE command (ACT), corresponding bank group and bank address (BG, BA) for the second memory bank, and row address (RA1) at CK_t=t4 (or 5 ns after t0) through the Command input 112, the Bank address input 114, and the Address input 116, respectively. The second ACTIVATE command (ACT) is directed to a row of another memory bank, and the time interval between the two commands (i.e., between t0 and t4) may correspond to the minimum time required between ACTIVATE commands to different banks (i.e., row to row delay, tRRD). Following the second external ACTVATE command and corresponding addresses, the circuitry 104 issues a second internal clock signal, a second internal ACTIVATE command (MACT), and corresponding bank group, bank and row addresses (BG, BA, RA1) to the MRAM dies 102 through the internal Clock input (MCLK) 170, the internal Command input 172, and the internal Address input (MA) 174, respectively. The second internal ACTIVATE command (MACT) may follow the first internal ACTIVATE command (ACT) without any delay because different MRAM banks 162 within a MRAM die 102 may operate independently. Accordingly, the second sensing operation of the magnetic memory cells corresponding to the second internal ACTIVATE command may commence before the first sensing operation corresponding to the first internal ACTIVATE command completes.

Unlike the time-based, free-running clock CK_t 110 of the external interface 106, the internal event-based clock (MCLK) 170 is deactivated after the two internal ACTIVATE commands. MCLK 170 is only active when initiating new internal commands, such as ACTIVATE and PRECHARGE, that may be executed by the MRAM dies 102 internally in a self-timed manner. The circuitry 104 ignores the external command DESELECT (DES), which disables the ability of DRAM to execute commands. The event-based clocking scheme of the present invention enables each MRAM die 102 to receive one or more new commands while still executing one or more current commands. While FIG. 6 shows the internal clock signal (MCLK) 170 is triggered from the falling edge of the external clock signal (CK_t) 110, the internal clock signal (MCLK) 170 may alternatively be triggered from the rising edge of the external clock signal (CK_t) 110.

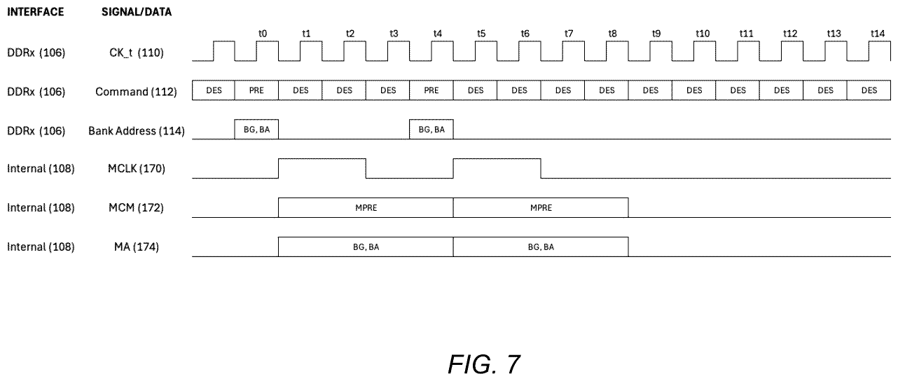

FIG. 7 is another exemplary timing diagram showing the relationship between the external DDR4 signals of the external interface 106 and corresponding internal signals of the internal interface 108 when the MRAM system 100 receives two external PRECHARGE commands via the external Command input 112 to close two open (active) rows of two different memory banks in the context of DRAM technology. The circuitry 104 of the MRAM system 100 receives the first PRECHARGE command (PRE), corresponding bank group and bank address (BG, BA) for the first memory bank at CK_t=t0 through the Command input 112 and the Bank address input 114, respectively. After receiving the first external PRECHARGE command (PRE) and corresponding addresses, the circuitry 104 issues an internal clock signal, an internal PRECHARGE command (MPRE), and corresponding bank group and bank address (BG, BA) to the MRAM dies 102 through the internal Clock input (MCLK) 170, the internal Command input 172, and the internal Address input (MA) 174, respectively. The internal clock signal, internal PRECHARGE command (MPRE), and corresponding bank group and bank address (BG, BA) may be issued as a packet by the circuitry 104. In response to the internal PRECHARGE command (MPRE), the data stored in the data buffer 164 is transferred to the previously activated magnetic memory cells of the MRAM bank 162, as specified by the internal addresses (BG, BA), for each MRAM die 102. The previously activated magnetic memory cells are deactivated after the data transfer from the data buffer 164 is completed.

With continued reference to FIG. 7, the circuitry 104 of the MRAM system 100 receives the second external PRECHARGE command (PRE), corresponding bank group and bank address (BG, BA) for the second memory bank at CK_t=t4 (or 5 ns after t0) through the Command input 112 and the Bank address input 114, respectively. The second PRECHARGE command (PRE) is directed to another memory bank, and the time interval between the two commands (i.e., between t0 and t4) may correspond to the minimum time required between PRECHARGE commands (i.e., row to row delay, tRRD). Following the second external PRECHARGE command and corresponding addresses, the circuitry 104 issues a second internal clock signal, a second internal PRECHARGE command (MPRE), and corresponding bank group and bank address (BG, BA) to the MRAM dies 102 through the internal Clock input (MCLK) 170, the internal Command input 172, and the internal Address input (MA) 174, respectively. The second internal PRECHARGE command (MPRE) may follow the first PRECHARGE command (MPRE) without any delay because different MRAM banks 162 within a MRAM die 102 may operate independently from each other. Accordingly, the data transfer from the data buffer 164 to the magnetic memory cells corresponding to the second internal PRECHARGE command (MPRE) may commence before the first data transfer corresponding to the first internal PRECHARGE command (MPRE) completes.

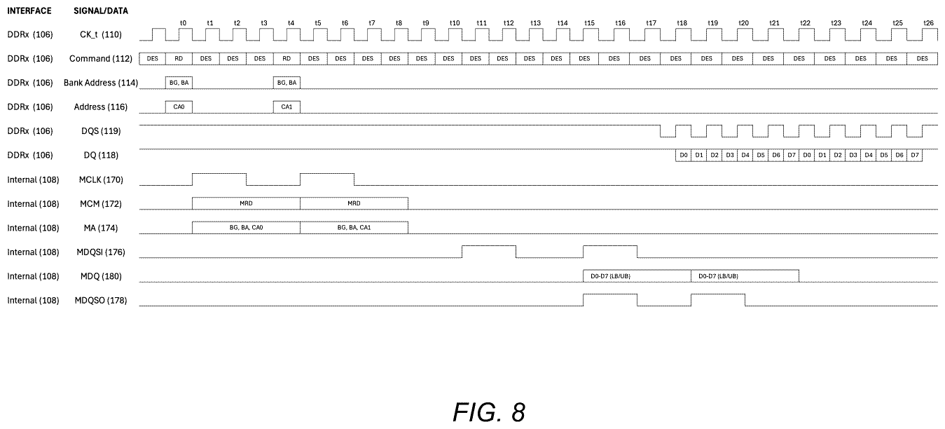

With continued reference to the above-described example of using four (N=4) 2 Gb MRAM dies 102, each with a 200 MHz clock speed and a 32-bit data bus (SDR), to emulate or mimic an 8 Gb DDR4-SDRAM chip with an 800 MHz clock speed and a 16 bit data bus, FIG. 8 is an exemplary timing diagram showing the relationship between the external DDR4 signals of the external interface 106 and corresponding internal signals of the internal interface 108 when the MRAM system 100 receives two external READ commands via the external Command input 112 to retrieve two blocks or bursts of data stored in the sense amplifiers/data latches from one or more previously activated rows of memory cells (i.e., page buffers) in the context of DRAM technology. The two external READ commands may be directed to an activated row (i.e., same page buffer) or two activated rows of two different DRAM memory banks (i.e., different page buffers). The standard burst length for each DDR4 READ or WRITE command may be 4 clock cycles, which correspond to 8 data cycles or a burst size of 128 bits for a 16-bit data bus.

The circuitry 104 of the MRAM system 100 receives the first external READ command (RD), corresponding bank group and bank address (BG, BA) for the first memory bank, and column address (CA0) at CK_t=t0 through the Command input 112, the Bank address input 114, and the Address input 116, respectively. The external Clock (CK_t) 110 may be center-aligned with Command input 112, the Bank address input 114, and the Address input 116, as shown. After receiving the first external READ command (RD) and corresponding addresses, the circuitry 104 issues an internal clock signal, a first internal READ command (MRD), and corresponding bank group, bank and column addresses (BG, BA, CA0) to the MRAM dies 102 through the internal Clock input (MCLK) 170, the internal Command input 172, and the internal Address input (MA) 174, respectively. The internal clock signal, internal READ command (MRD), and corresponding bank group, bank and column addresses (BG, BA, CA0) may be issued as a packet by the circuitry 104. In response to the internal READ command (MRD), the first burst of read data is transferred from the data buffer 164 to the read FIFO buffer 166. Following the issuance of the first internal READ command (MRD) and a delayed period which may allow time for the proper transfer of the read data from the data buffer 164 to the read FIFO buffer 166, the circuitry 104 issues a first strobe signal to the MRAM dies 102 through the Data strobe input (MDQSI) 176. Following the strobe signal from MDQSI 176, the first read data (D0-D7, which correspond to the read data from all dies) is transferred from the read FIFO buffer 166 to the circuitry 104 through MDQ 180, together with another strobe signal from MDQSO 178 to ensure the first read data is accurately captured by the circuitry 104. Before the read data is completely transferred from the MRAM dies 102 to the circuitry 104 through MDQ 180, the circuitry 104 may initiate the transfer of the read data over 8 data cycles (D0-D7), which correspond to the burst length of the DDR4 interface 106, to the memory controller or CPU through DQ 118 and the strobe signal through DQS 119 to ensure the first burst of read data is accurately captured by the memory controller or CPU. For the current example, all four MRAM dies 102, each with a 32-bit data bus, can collectively transfer 128 bits of read data in one data cycle (SDR), which match the burst data size of 128 bits spanning 8 data cycles (DDR) for the external DDR4 interface 106.

With continued reference to FIG. 8, the circuitry 104 of the MRAM system 100 receives the second external READ command (RD), corresponding bank group and bank address (BG, BA) for the second memory bank, and column address (CA1) at CK_t=t4 (or 5 ns after t0) through the Command input 112, the Bank address input 114, and the Address input 116, respectively. The second external READ command (RD) may be directed to the same open row or another open row of another memory bank, and the time interval between the two commands (i.e., between t0 and t4) may correspond to the minimum time required between two READ commands (i.e., column-to-column delay, tCCD). Following the second external READ command and corresponding addresses, the circuitry 104 issues a second internal clock signal, a second internal READ command (MRD), and corresponding bank group, bank and column addresses (BG, BA, CA1) to the MRAM dies 102 through the internal Clock input (MCLK) 170, the internal Command input 172, and the internal Address input (MA) 174, respectively. The second internal READ command (MRD) may follow the first internal READ command (MRD) without any delay. In response to the second internal READ command (MRD), the second burst of read data is transferred from the data buffer 164 to the read FIFO buffer 166. Following the issuance of the second internal READ command (MRD) and a delayed period, the circuitry 104 issues a second strobe signal to the MRAM dies 102 through the Data strobe input (MDQSI) 176. Following the second strobe signal from MDQSI 176, the second read data (D0-D7, which correspond to the read data from all dies) is transferred from the read FIFO buffer 166 to the circuitry 104 through MDQ 180, together with another strobe signal from MDQSO 178 to ensure the second read data is accurately captured by the circuitry 104. Before the read data is completely transferred from the MRAM dies 102 to the circuitry 104 through MDQ 180, the circuitry 104 may initiate the transfer of the read data over 8 data cycles (D0-D7), which correspond to the burst length of the DDR4 interface 106, to the memory controller or CPU through DQ 118 and the strobe signal through DQS 119 to ensure the second burst of read data is accurately captured by the memory controller or CPU.

It is worth noting that the second strobe signal through MDQSI 176 overlaps with the first read data through MDQ 180 and accompanied strobe signal through MDQSO 178. The transfer of the second read data between the MRAM dies 102 and the circuit 104 also overlaps with the transfer of the first burst of read data between the circuit 104 and the memory controller or CPU. The MRAM system 100 may allow operations corresponding to multiple commands to overlap to reduce latency. For example, if the MRAM system 100 were to receive a third external READ command, then the third strobe signal through MDQSI 176 would overlap with the transfer of the second read data to the circuit 104 via MDQ 180 and the transfer of the first burst of read data to the memory controller or PC via DQ 118.

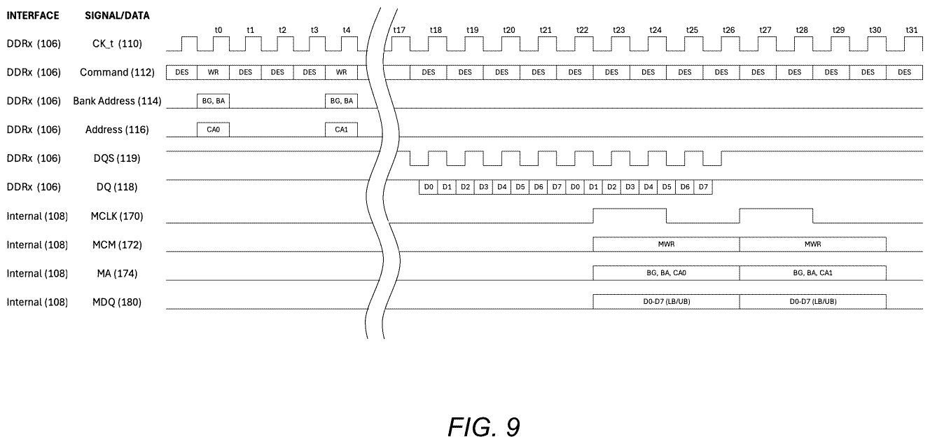

FIG. 9 is an exemplary timing diagram showing the relationship between the external DDR4 signals of the external interface 106 and corresponding internal signals of the internal interface 108 when the MRAM system 100 receives two external WRITE commands via the external Command input 112 to transfer two blocks or bursts of data from the memory controller or CPU to the sense amplifiers/data latches corresponding to one or two previously activated rows of memory cells in the context of DRAM technology. The two external write commands may be directed to an activated row (same page buffer) or two activated rows of two different DRAM memory banks (different page buffers).

The circuitry 104 of the MRAM system 100 receives the first external WRITE command (WR), corresponding bank group and bank address (BG, BA) for the first memory bank, and column address (CA0) at CK_t=t0 through the Command input 112, the Bank address input 114, and the Address input 116, respectively. Following a delay period (i.e., CAS write latency, CWL), the circuitry 104 of the MRAM system 100 receives the first burst of write data (D0-D7) and accompanied strobe signal at CK_t=t18 via DQ 118 and DQS 119, respectively. After receiving the first burst of write data (D0-D7), the circuitry 104 issues an internal clock signal, a first internal WRITE command (MWR), corresponding bank group, bank and column addresses (BG, BA, CA0), and the first burst of write data (D0-D7) to the MRAM dies 102 through the internal Clock input (MCLK) 170, the internal Command input 172, the internal Address input (MA) 174, and the Data input/output (MDQ) 180, respectively. In response to the internal WRITE command (MWR), the first burst of write data (D0-D7) is transferred to the DIN register 168 and then to the data buffer 164. For the current example, all four MRAM dies 102, each with a 32-bit data bus, can collectively receive 128 bits of write data in one data cycle (SDR), which match the burst data size of 128 bits spanning 8 data cycles (DDR) for the external DDR4 interface 106.

With continued reference to FIG. 9, the circuitry 104 of the MRAM system 100 receives the second external WRITE command (WR), corresponding bank group and bank address (BG, BA) for the second memory bank, and column address (CA1) at CK_t=t4 (or 5 ns after t0) through the Command input 112, the Bank address input 114, and the Address input 116, respectively. The second external WRITE command (WR) may be directed to the same open row (page buffer) or another open row of another memory bank, and the time interval between the two commands (i.e., between t0 and t4) may correspond to the minimum time required between two WRITE commands (i.e., column-to-column delay, tCCD). Following another delay period, the circuitry 104 of the MRAM system 100 receives the second burst of write data (D0-D7) and accompanied strobe signal at CK_t=t22 via DQ 118 and DQS 119, respectively. After receiving the second burst of write data (D0-D7), the circuitry 104 issues an internal clock signal, a first internal WRITE command (MWR), corresponding bank group, bank and column addresses (BG, BA, CA1), and the second burst of write data (D0-D7) to the MRAM dies 102 through the internal Clock input (MCLK) 170, the internal Command input 172, the internal Address input (MA) 174, and the Data input/output (MDQ) 180, respectively. In response to the internal WRITE command (MWR), the first burst of write data (D0-D7) is transferred to the DIN register 168 and then to the data buffer 164.

While the present invention has been shown and described with reference to certain preferred embodiments, it is to be understood that those skilled in the art will no doubt devise certain alterations and modifications thereto which nevertheless include the true spirit and scope of the present invention. Thus the scope of the invention should be determined by the appended claims and their legal equivalents, rather than by examples given.

What is claimed is:

1. A magnetic memory system comprising:
a plurality of magnetic random access memory (MRAM) dies, each MRAM die including a plurality of magnetic memory cells; and
a circuitry for controlling the MRAM dies, the circuitry communicating with devices external to the magnetic memory system through an external interface and the MRAM dies through an internal interface,
wherein the external interface is in compliance with a version of Double Data Rate (DDR) standards and has a data transfer rate corresponding to a sum of data transfer rates of the MRAM dies.

2. The magnetic memory system of claim 1, wherein the external interface has a clock frequency that is a multiple of a clock frequency of each MRAM die.

3. The magnetic memory system of claim 2, wherein the clock frequency of the external interface corresponds to a sum of the clock frequencies of the MRAM dies.

4. The magnetic memory system of claim 1, wherein the external interface has a burst data length spanning multiple clock cycles that correspond to one clock cycle of each MRAM die.

5. The magnetic memory system of claim 1, wherein the circuitry resides on an application-specific integrated circuit (ASIC) or field programmable gate arrays (FPGA) die.

6. The magnetic memory system of claim 5, wherein the ASIC or FPGA die and the MRAM dies are packaged together.

7. The magnetic memory system of claim 5, wherein the ASIC or FPGA die and the MRAM dies are separately attached to a printed circuit board.

8. The magnetic memory system of claim 1, wherein each of the plurality of magnetic memory cells includes a magnetic tunnel junction (MTJ) and an access transistor electrically connected in series.

9. The magnetic memory system of claim 1, wherein the external interface is in compliance with a DDR4 standard.

10. The magnetic memory system of claim 1, wherein the internal interface uses an event-based clocking scheme.

11. The magnetic memory system of claim 1, wherein read data is transferred from a data buffer of each MRAM die to the external interface in response to a READ command from the external interface.

12. The magnetic memory system of claim 11, wherein the read data is transferred without accessing any of the magnetic memory cells in response to the READ command from the external interface.

13. The magnetic memory system of claim 1, wherein a burst of write data is transferred from the external interface to data buffers of the MRAM dies in response to a WRITE command from the external interface.

14. The magnetic memory system of claim 13, wherein the burst of write data is transferred without accessing any of the magnetic memory cells in response to the WRITE command from the external interface.

15. The magnetic memory system of claim 1, wherein each MRAM die includes multiple memory banks, each memory bank including multiple arrays of magnetic memory cells, each array of magnetic memory cells including multiple sub-arrays of magnetic memory cells, each sub-array of magnetic memory cells being arranged in rows and columns with a plurality of parallel bit lines connecting each sub-array of magnetic memory cells along a column direction.

16. The magnetic memory system of claim 15, wherein the plurality of parallel bit lines are connected to a dedicated sense amplifier through a multiplexer (MUX).

17. The magnetic memory system of claim 16, wherein data stored in a logical row of magnetic memory cells is transferred to a data buffer in each MRAM die in response to an ACTIVATE command from the external interface.

18. The magnetic memory system of claim 17, wherein the logical row of magnetic memory cells comprises one magnetic memory cell from each sub-array of magnetic memory cells of a memory bank.

19. The magnetic memory system of claim 16, wherein data stored in a data buffer is transferred to a logical row of magnetic memory cells in each MRAM die in response to an external PRECHARGE command.

20. The magnetic memory system of claim 19, wherein the logical row of magnetic memory cells comprises one magnetic memory cell from each sub-array of magnetic memory cells of a memory bank.
